(19) United States
(12) Patent Application Publication
(10) Pub. No.: US 2024/0266382 A1
(43) Pub. Date: Aug. 8, 2024

(54) SOLID-STATE AMORPHOUS SELENIUM AVALANCHE DETECTOR WITH HOLE BLOCKING LAYER

(71) Applicants: THE RESEARCH FOUNDATION FOR THE STATE UNIVERSITY OF NEW YORK, Albany, NY (US); BROOKHAVEN SCIENCE ASSOCIATES, LLC, Upton, NY (US)

(72) Inventors: Atreyo MUKHERJEE, Stony Brook, NY (US); Wei ZHAO, East Setauket, NY (US); Amirhossein GOLDAN, Stony Brook, NY (US); Le Thanh Triet HO, Centereach, NY (US); Anthony R. LUBINSKY, Port Jefferson, NY (US); Adrian HOWANSKY, Centereach, NY (US); Jann STAVRO, Stony Brook, NY (US); D. Peter SIDDONS, Upton, NY (US); Abdul Khader RUMAIZ, Nesconset, NY (US)

(73) Assignees: THE RESEARCH FOUNDATION FOR THE STATE UNIVERSITY OF NEW YORK, Albany, NY (US); BROOKHAVEN SCIENCE ASSOCIATES, LLC, Upton, NY (US)

(21) Appl. No.: 18/561,840

(22) PCT Filed: May 19, 2022
(86) PCT No.: PCT/US2022/030043

§ 371 Date: Nov. 17, 2023

Related U.S. Application Data
(60) Provisional application No. 63/190,394, filed on May 19, 2021.

(51) Int. Cl. H01L 27/146

(52) U.S. Cl. CPC H01L 27/14665; H01L 27/14692

(57) ABSTRACT

A solid-state photomultiplier with a high-k dielectric hole blocking layer (HBL) is provided. The HBL may include a n-type material. The photomultiplier may comprise an amorphous selenium (a-Se) bulk layer. The HBL may be a non-insulating layer. The photomultiplier may also comprise an electron blocking layer (EBL). The EBL may comprise a p-type material. The p-type material may also have a high k dielectric. The a-Se layer may be sandwiched between the HBL and the EBL. Methods for manufacturing a solid-state photomultiplier are also provided.

### CROSS-REFERENCE TO RELATED APPLICATION

This application claims the benefit of and priority to U.S. Provisional Application Ser. No. 63/190,394 filed on May 19, 2021, the entirety of which is incorporated by reference.

### STATEMENT REGARDING FEDERALLY SPONSORED RESEARCH

This invention was made with government support under EB026644 awarded by National Institutes of Health and DE-SC0012704 awarded by the Department of Energy. The government has certain rights in the invention.

### FIELD OF THE DISCLOSURE

This disclosure relates to solid-state radiation imaging detectors and methods of manufacturing the same.

### BACKGROUND

Efficient sensing and imaging of low-light signals down to the single photon level with a true solid-state photomultiplier has been a long-standing quest with a wide range of applications in astronomy and spectroscopy, medical imaging, and the rapidly developing field of quantum optics and quantum information science. Low-light detection technology, which utilizes the avalanche phenomena for increasing the signal-to-noise ratio (SNR), is an extremely powerful tool that enables a deeper understanding of more sophisticated phenomena. The measurement under light-starved conditions offers the following unique advantages: nondestructive analysis of a substance, high-speed time-of-flight properties, and single-photon detectability.

One known commercial detector for low-light detection with high dynamic range and linear mode operation is the vacuum photo multiplier tube (PMT). Although the main advantage of PMTs is high gain (typically 10⁵-10⁸) with low excess noise and room temperature operation, they are bulky and fragile, have poor quantum efficiency in the visible spectrum, are insensitive to infrared light and highly sensitive to magnetic fields. In comparison, key advantages of solid-state technology are ruggedness, compact size, insensitivity to magnetic fields, and excellent uniformity of response. In practical avalanche detectors, however, the amount of enhancement in SNR is often severely limited by excess noise caused by the stochastic nature of the avalanche impact ionization process and the optimal SNR typically occurs at very low gain values.

Another known detector uses amorphous selenium (a-Se) as a bulk avalanche i-layer. Amorphous Selenium (a-Se) based solid-state detectors have some very distinct advantages. For example, a-Se is readily produced uniformly over a larger area at substantially lower costs, as compared to crystalline semiconductors. Additionally, a-Se is the only amorphous material that produces impact ionization avalanche gain at high fields and is the only exception to the Webb's criterion because only holes become hot carriers and undergo avalanche multiplication, and consequently, avalanche selenium devices are linear-mode devices with a negligibly small excess noise. a-Se has been used in optical cameras. For example, the avalanche gain in a-Se enabled the development of the first optical camera with more sensitivity than human vision and, for example, capable of capturing astronomical phenomena such as auroras and solar eclipses.

a-Se also has a wide bandgap (2.1 eV) room-temperature semiconductor with ultra-low thermal generation of carriers even at high fields. Moreover, the a-Se layer can be deposited over thin-film-transistors (TFT) in the read-out electronics at temperatures that would not damage the underlying active-matrix readouts (below ˜200° C.).

However, even with all of these advantageous, the development of solid-state avalanche a-Se devices with a 2D-array of pixelated readout (detector) has been difficult to achieve, especially due to an inefficient hole blocking layer(s). For example, at substantially high electric fields required for impact ionization, an optimized termination is required to reach stable blocking with minimum dark or leakage currents. Moreover, it is a technological challenge to avoid possible dielectric breakdown of the detector when the electric field experiences local enhancement at the hole blocking layer/high-voltage-metal-electrode interface, thus leading to enhanced hole injection from the high voltage electrode. This uncontrolled injection causes a high current flow that can induce a phase transition due to Joule heating, thus leading to crystallization in the a-Se layer. This crystallization results in a drop of resistivity, enabling an even higher current flow in the a-Se layer, which further increases Joule heating, resulting in a runaway effect which ultimately leads to a dielectric breakdown of the device.

### SUMMARY

Accordingly, disclosed is a photomultiplier which comprises a first electrode, a hole blocking layer (HBL), a photoconductive layer, an electron blocking layer (EBL) and a second electrode. The photoconductive layer may comprise amorphous selenium (a-Se). The HBL may comprises a n-type material having a dielectric constant of at least 50. The EBL may comprise a p-type material. The a-Se photoconductive layer may be between the EBL and the HBL. The HBL may be between the first electrode and the a-Se layer. The EBL may be between the second electrode and the a-Se layer.

In an aspect of the disclosure, the dielectric constant of the n-type material may be between about 50 and about 3000. For example, the n-type material may be selected from a group consisting of Barium Titanate, Strontium Titanate, Barium Strontium Titanate, and Titanium Oxide. In some aspects, the n-type material may be Strontium Titanate (SrTi0₃) (“STO”). The STO may be formed as a single crystal or thin film. The single crystal may have a dielectric constant of about 300.

In an aspect of the disclosure, the photomultiplier may have an avalanche gain about 150 at an applied bias of about 3750 V.

In an aspect of the disclosure, the HBL may have a thickness of about 50 nm to 1 μm.

In an aspect of the disclosure, the a-Se layer may have a thickness between about 50 nm and about 35 μm, inclusive. The thickness may be based on an application.

In an aspect of the disclosure, the p-type material may have a dielectric constant of at least 50. For example, the p-type material may be Ni0₂.

In an aspect of the disclosure, the first electrode may be transparent. For example, the first electrode may be made of indium tin oxide (ITO).

In an aspect of the disclosure, the photomultiplier may further comprise a readout device.

Also disclosed is a photomultiplier which comprises a first electrode, a hole blocking layer (HBL), a photoconductive layer, an electron blocking layer (EBL) and a second electrode. The photoconductive layer may comprise amorphous selenium (a-Se). The HBL may comprises Strontium Titanate (SrTi0₃) (“STO”). The EBL may comprise a p-type material. The a-Se photoconductive layer may be between the EBL and the HBL. The HBL may be between the first electrode and the a-Se layer. The EBL may be between the second electrode and the a-Se layer.

In an aspect of the disclosure, the STO may be formed as a single crystal or thin film. The single crystal may have a dielectric constant of about 300.

In an aspect of the disclosure, the photomultiplier may have an avalanche gain about 150 at an applied bias of about 3750 V.

In an aspect of the disclosure, the p-type material may be Ni0₂.

Also disclosed is a method of manufacturing a photomultiplier. The method may comprise fabricating a first part of the photomultiplier, fabricating a second part of the photomultiplier and combining the first part and the second part.

The fabrication of the first part may comprise depositing an electron blocking layer comprising a p-type material on a readout device; and depositing a first portion of a-Se photoconductive layer having a first thickness of the electron blocking layer.

The fabrication of the second part may comprise depositing a hole blocking layer comprising a n-type material having a dielectric constant of at least 50 on a substrate; and depositing a second portion of a-Se photoconductive layer having a second thickness on the hole blocking layer. The substrate may comprise an electrode.

The combining may comprise heating the first part and the second part to at least a glass transition temperature of the a-Se photoconductive layer; and applying pressure to fuse the first portion of the a-Se photoconductive layer and the second portion of the a-Se photoconductive layer thereby combining the first part and the second part.

Another electrode may be formed on a readout device.

In an aspect of the disclosure, the first thickness may be the same as the second thickness.

In an aspect of the disclosure, the n-type material is selected from a group consisting of Barium Titanate, Strontium Titanate, Barium Strontium Titanate, and Titanium Oxide. For example, the n-type material may Strontium Titanate (SrTi0₃) (“STO”).

In an aspect of the disclosure, the electron blocking layer may comprise Ni0₂.

Also disclosed is another method of manufacturing a photomultiplier. The method may comprise depositing an electron blocking layer comprising a p-type material on a readout device where the readout device has a common electrode, thermally deposit a-Se layer on the electron blocking layer, depositing at a temperature less than a glass transition temperature of the a-Se layer, hole blocking layer comprising a n-type material having a dielectric constant of at least 50 and depositing another electrode on the hole blocking layer.

In an aspect of the disclosure, the hole blocking layer is deposited using RF sputtering.

In an aspect of the disclosure, the n-type material is selected from a group consisting of Barium Titanate, Strontium Titanate, Barium Strontium Titanate, and Titanium Oxide. For example, the n-type material may Strontium Titanate (SrTi0₃) (“STO”).

In an aspect of the disclosure, the electron blocking layer may comprise Ni0₂.

### BRIEF DESCRIPTION OF THE DRAWINGS

FIG. 1 illustrates an example of a solid-state amorphous selenium avalanche detector (“avalanche detector”) in accordance with aspects of the disclosure;

FIG. 2 illustrates an example of a method of fabricating an avalanche detector in accordance with aspects of the disclosure;

FIG. 3A illustrates an example of a method of fabricating the first part of the avalanche detector in accordance with aspects of the disclosure;

FIG. 3B illustrates an exploded view of a representation of the first part of the avalanche detector in accordance with aspects of the disclosure;

FIG. 4A illustrates an example of a method of fabricating the second part of the avalanche detector in accordance with aspects of the disclosure;

FIG. 4B illustrates an exploded view of a representation of the second part of the avalanche detector in accordance with aspects of the disclosure;

FIG. 5A illustrates an example of a method of combining the first part and the second part of the avalanche detector in accordance with aspects of the disclosure;

FIG. 5B illustrates an exploded view of a representation of the avalanche detector showing both portions of the a-Se layer in accordance with aspects of the disclosure;

FIG. 6A illustrates another example of a method of fabricating the avalanche detector in accordance with aspects of the disclosure;

FIG. 6B illustrates an exploded view of a representation of the avalanche detector fabricated as shown in FIG. 6A in accordance with aspects of the disclosure;

FIG. 7 illustrates a step-by-step process of fabricating a test detector in accordance with aspects of the disclosure, where the test detector is a planar n-i detector;

FIG. 8 illustrates a schematic of the test detector in accordance with aspects of the disclosure;

FIG. 9 illustrates the test detector under testing (DUT);

FIG. 10 illustrates the measurement results of an avalanche gain as a function of the applied bias voltage in accordance with aspects of the disclosure;

FIG. 11 illustrates the measurement results of a dark current density as a function of the applied bias voltage in accordance with aspects of the disclosure;

FIG. 12 illustrates simulation and measurement results of excess noise factor of a detector in accordance with aspects of the disclosure and comparison with other devices;

FIG. 13 illustrates measured and predicted effective quantum efficiency verses electric field;

FIG. 14 illustrates simulation results showing a comparison of the electric field in the i-layer from different n-layers;

FIG. 15 illustrates a simulated energy band diagram for a detector in accordance with aspects of the disclosure;

FIG. 16 illustrates a simulated electric field in the HBL versus the a-Se layer in accordance with aspects of the disclosure;

FIG. 17 illustrates a simulated electric field as a function of the applied bias in accordance with aspects of the disclosure; and

FIG. 18 illustrates a simulated energy band diagram for another detector in accordance with aspects of the disclosure with both p and n blocking layers.

### DETAILED DESCRIPTION

In accordance with aspects of the disclosure, a solid-state avalanche detector has a high-κ dielectric hole-blocking layer (HBL). For purposes of the describes, “high-κ dielectric” means a dielectric greater than 50. The “high-κ dielectric” also refers to a dielectric less than 3000. Advantageously, the HBL as described herein decreases the electric field at the HBL/high-voltage metal electrode interface which limits Schottky injection from the high voltage electrode, which in turn prevents Joule heating from crystalizing an a-Se layer (bulk layer). This avoids the runaway effect. The HBL as described herein also avoids early dielectric breakdown on the detector, which may enable achieving avalanche gains equal to the theoretical gain of the a-Se layer and comparable to vacuum PMTs (on the order of 10⁶). Thus, the HBL as described herein enables the solid-state avalanche detector to be reliable and have a repeatable impact ionization gain with the irreversible breakdown.

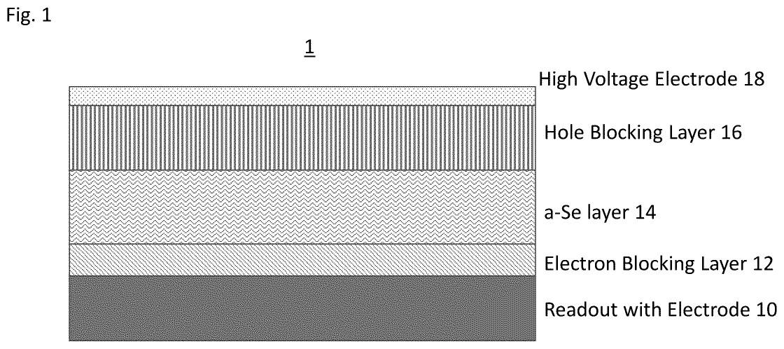

FIG. 1 illustrates a solid-state amorphous selenium avalanche detector 1 in accordance with aspects of the disclosure (avalanche detector 1). The avalanche detector 1 comprises a readout 10 (also referred to as “ROIC” or “readout device”. In an aspect of the disclosure, the readout 10 may comprise the common electrode as shown in FIG. 1. However, in other aspects, the common electrode may be separate and deposited on the readout in a known manner. In an aspect of the disclosure, the common electrode may have a thickness about 20 nm to about 200 nm.

The readout 10, may either be used for photon counting (CMOS substrate) or energy integration (CMOS or TFT substrate) applications. A thin-film-transistor (TFT) substrate or a complementary metal-oxide-semiconductor (CMOS) substrate can be utilized with a previously patterned common/ground electrode to form the readout 10. The common/ground electrode is preferably formed of conductive materials that include Aluminum (Al), Chromium (Cr), Tungsten (W), Indium tin oxide (ITO), and Zinc oxide (ZnO). The readout 10 further includes the circuitry to bias a readout (via data switches) and output the signals representing the counts (when photon counting). For example, the readout 10 may have data lines D1-DN. The data lines may be coupled to amplifiers. The readout 10 may include a matrix of active elements, e.g., CMOS or TFT (with a storage capacitor). Each pixel has an active area and a fill factor.

The readout 10 may output analog signals to an analog to digital converter (“ADC”).

The avalanche detector 1 also comprises an electron blocking layer 12. In an aspect of the disclosure, the electron blocking layer 12 (EBL) may comprise a material that is a p-type material (with respect to a-Se). The EBL 12 may have a high-κ dielectric. In an aspect of the disclosure, the EBL may be made of NiO₂. However, the EBL 12 is not limited to being made of NiO₂. Other p-type, high-κ dielectric may be used to isolate the a-Se layer 14 from the common electrode. The EBL 12 blocks or prevents electrons from being injected from the common electrode into the a-Se layer 14. The EBL 12 (p-type material) decreases the electric field at the EBL/common electrode interface. In an aspect of the disclosure, the EBL 12 may have a thickness of about 50 nm to about 1 μm.

The avalanche detector 1 also comprises an a-Se layer 14. The a-Se layer 14 is a photoconductive layer. The EBL 12 is between the a-Se layer 14 and the common electrode (and readout 10). The thickness of the a-Se layer 14 may depend on the application. For example, the a-Se layer 14 may have a thickness of about 500 nm to about 35 μm. Selenium has a permittivity of 6.

The avalanche detector 1 also comprises the HBL 16. As described above, the HBL 16 reduces an electric field at the HBL/high-voltage electrode interface (hole injecting interface). The higher the dielectric of the HBL 16 is, the more the electric field is reduced. In an aspect of the disclosure, the HBL 16 may be made of a material that is an n-type material with respect to the a-Se layer 14. For example, Strontium Titanate (SrTiO₃) (also referred to as STO) may be used as the n-type material. The κ value for SrTiO₃ may depend on how it is formed. For example, a single crystal STO may have a κ about 300. However, when the STO is fabricated as a thin film, the STO may have a κ value lower. In aspect of the disclosure, the single crystal STO may be used in a detector for a single pixel, whereas the thin film may be used for a detector 1 having an array of pixels. Other materials, such as other n-type perovskite-type materials may be used. However, the materials are not limited to perovskites.

Other materials such as Barium Titanate, Barium Strontium Titanate, and Titanium Oxide may be used. Barium Titanate has a reported κ of about 3000. Barium Strontium Titanate has a reported κ of about 680. Titanium Oxide has a reported κ up to 70.

The HBL 16 isolates the a-Se layer 14 from the high voltage electrode 18 (e.g., blocking the holes from being injected from the high voltage electrode 18 into the a-Se layer 14).

Thus, by sandwiching the a-Se layer 14 between the high κ blocking layers (EBL 12, HBL 16), the a-Se layer 14 is protected. Similar to the EBL 12, the HBL 16 may have a thickness of about 50 nm to about 1 μm.

The avalanche detector 1 also comprises the high voltage electrode 18 (HVE). In an aspect of the disclosure, the HVE 18 may be transparent to a target wavelength band. For example, the HVE 18 may be formed of indium tin oxide (ITO). The ITO may be transparent to wavelengths above 300 nm. However, the HVE 18 is not limited to ITO and other transparent materials may be used. For example, indium gallium zinc oxide (IGZO) may be used. While it is preferred that the HVE 18 is made from a transparent material to allow light through, it is not necessary for the common electrode to be made of a transparent material and the common electrode may be any of the conductive materials as mentioned above. Similar to the common electrode, the HVE 18 may have a thickness of about 20 nm to about 200 nm.

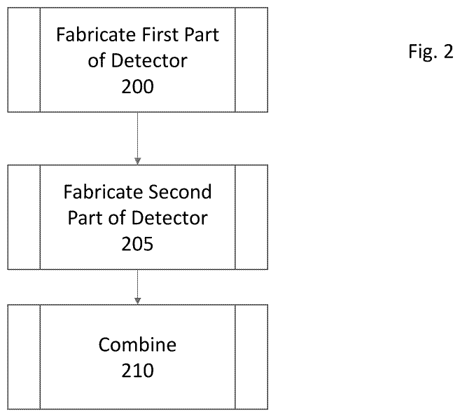

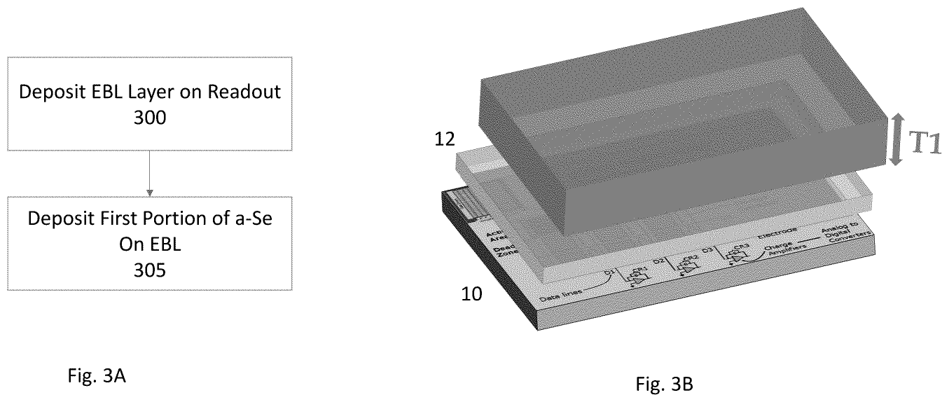

FIG. 2 illustrates an example of a method of fabricating an avalanche detector 1 in accordance with aspects of the disclosure. In accordance with aspects of the disclosure, the avalanche detector 1 may be fabricated in two separate parts (First Part and Second Part) and subsequently fused together. At 200, the first part of the detector may be fabricated. FIG. 3A illustrates an example of a method of fabricating the first part of the avalanche detector 1. FIG. 3B illustrates an exploded view of a representation the first part of the avalanche detector 1. This method may be used to fabricate the avalanche detector 1 because the glass transition temperature of a-Se is relatively low (about 50° C.). Any material deposited on a-Se must be deposited below 50° C. or a-Se will crystalize. This method removes the low temperature deposition requirement on a-Se to prevent crystallization. At 300, the EBL 12 may be deposited on the readout 10 at a first temperature. In an aspect of the disclosure, the first temperature may be above 50° C. In this aspect of the disclosure, the common electrode is included in the readout 10. The common electrode may be deposited via physical vapor deposition.

At 305, a portion of the a-Se layer 14 is deposited on the EBL layer 12. As shown in FIG. 3B, this portion has a thickness of T1. In some aspects, T1 may be half of the target thickness of the a-Se layer 14. However, the thickness of T1 is not limited to half. In an aspect of the disclosure, the a-Se may be thermally deposed via a physical vapor deposition (PVD). As shown in FIG. 3B, the first portion has the readout 10, the EBL 12 and a portion T1 of the a-Se.

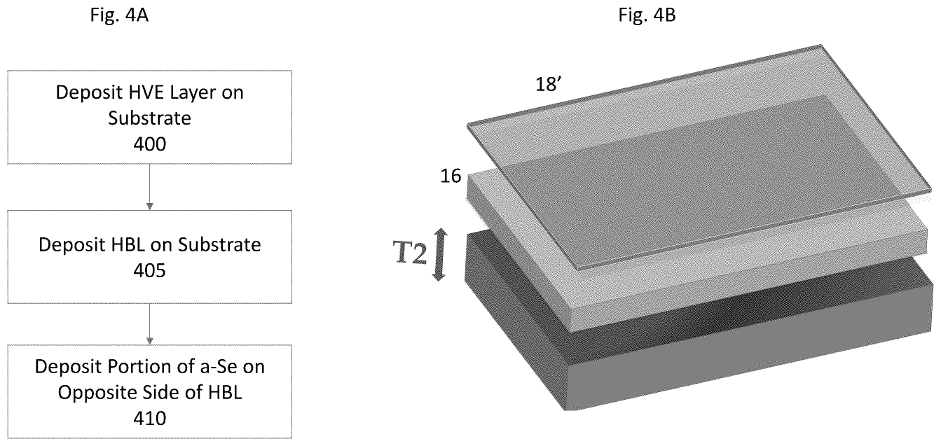

At 205, the second part of the avalanche detector 1 may be fabricated. FIG. 4A illustrates an example of a method of fabricating the second part of the avalanche detector 1. FIG. 4B illustrates an exploded view of a representation the second part of the avalanche detector 1.

At 400, the HVE 18′ is formed. In an aspect of the disclosure, a glass substrate may be used. The electrode (e.g., ITO) may be RF sputtered to a target thickness. The target thickness may be about 20 nm to about 200 nm as described above. At 405, the HBL 16 may be deposited by RF sputtering the layer on the glass substrate (having the electrode). The HBL 16 will be in contact with the HVE 18′. The HBL 16 may be deposited as a thin film having a target thickness.

In other aspects of the disclosure, 400/405 may be omitted when a single crystal STO is used as the HBL 16. The rigidly of the single crystal STO eliminates a need for the glass substrate and the HVE 18 may be deposited directly on the STO (as the substrate).

At 410, a portion of the a-Se layer 14 is deposited on the HBL layer 16. As shown in FIG. 4B, this portion has a thickness of T2. In some aspects, T2 may be half of the target thickness of the a-Se layer 14. However, the thickness of T2 is not limited to half. In an aspect of the disclosure, the a-Se may be thermally deposed via a physical vapor deposition (PVD). As shown in FIG. 4B, the second portion has the HVE 18′, the HBL 16 and a portion T2 of the a-Se. The HVE in FIG. 4B is identified as 18′ since the glass substrate may be present.

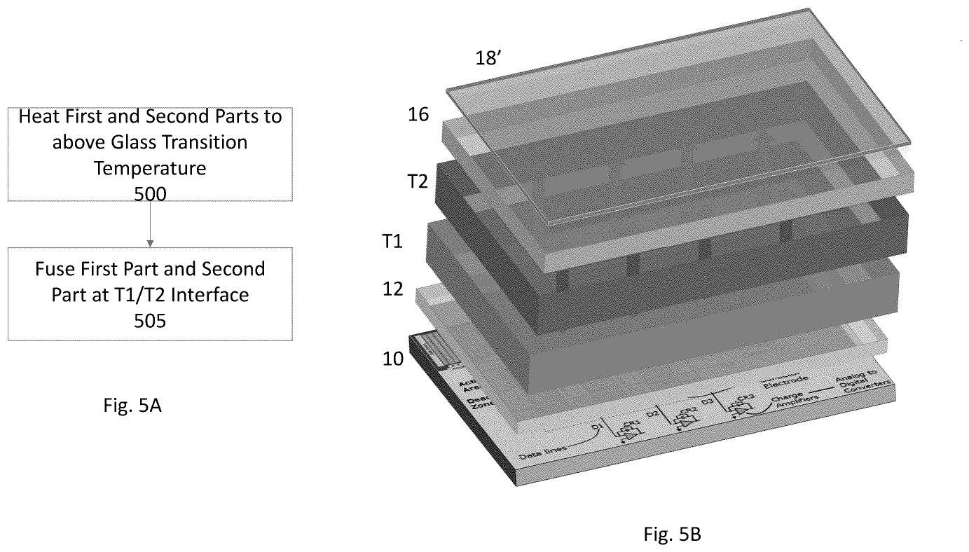

At 210, the first part and the second part of the avalanche detector 1 may be combined. FIG. 5A illustrates an example of a method of combining the first part and the second part of the avalanche detector 1. At 500, the first part and the second part of the avalanche detector 1 are heated to above the glass transition temperature of the a-Se layer 14 (e.g., above 50° C.). Above the glass transition temperature, the a-Se become a viscous, rubber-like adhesive which allows the first part and the second part to fuse together. At 505, while the first part and the second part are heated, pressure is exerted on the first part and the second part to fuse the two portions of the a-Se layer (T1 and T2). FIG. 5B shows an exploded view of a representation of the avalanche detector 1 having the two parts with T1/T2. T1/T2 would be fused together at 505 to form the a-Se layer 14. The arrows in FIG. 5B represent the fusion of T1/T2.

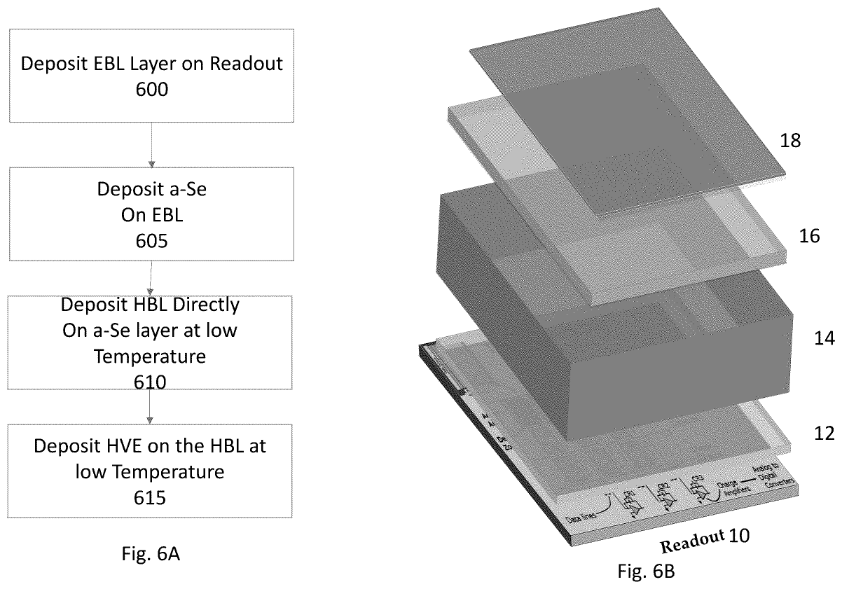

In another aspect of the disclosure, the avalanche detector 1 may be fabricated without dividing the same into the first part and the second part and fabricated under a low temperature (e.g., below the glass transition temperature). FIG. 6A illustrates another method of fabricating the avalanche detector 1 in accordance with aspects of the disclosure. FIG. 6B illustrates a representation of the avalanche detector 1 fabricated in accordance with FIG. 6A.

At 600, the EBL layer 12 is deposited on the readout 10. The readout 10 acts as the substrate for the EBL layer 12. Once again, the common electrode may be in the readout 10. At 605, the a-Se layer 14 is deposited on the EBL layer 12 (directly) such that the a-Se layer 14 is in direct contact with the EBL layer 12. In an aspect of the disclosure, the a-Se may be deposited using PVD to achieve a target thickness. At 610, the HBL layer 16 is directly deposited on the a-Se layer 14 using low temperature RF sputtering. The low temperature RF sputtering (below about 50° C.) prevents crystallization of the a-Se. The RF sputtering may achieve the target thickness for the HBL layer 16. At 615, the HVE 18 is deposited on the HBL layer 16. FIG. 6B depicted a representation of the deposited EBL layer 12 (on the readout 10), the a-Se layer 14 (deposited on the EBL layer 12), the HBL layer 16 (deposited on the a-Se layer 14) and the HVE 18 (deposited on the HBL layer 16). The methods depicted in FIGS. 2 and 6A are examples of the p-i-n fabrication process (holes travel toward the pixels).

### Measurements and Simulations

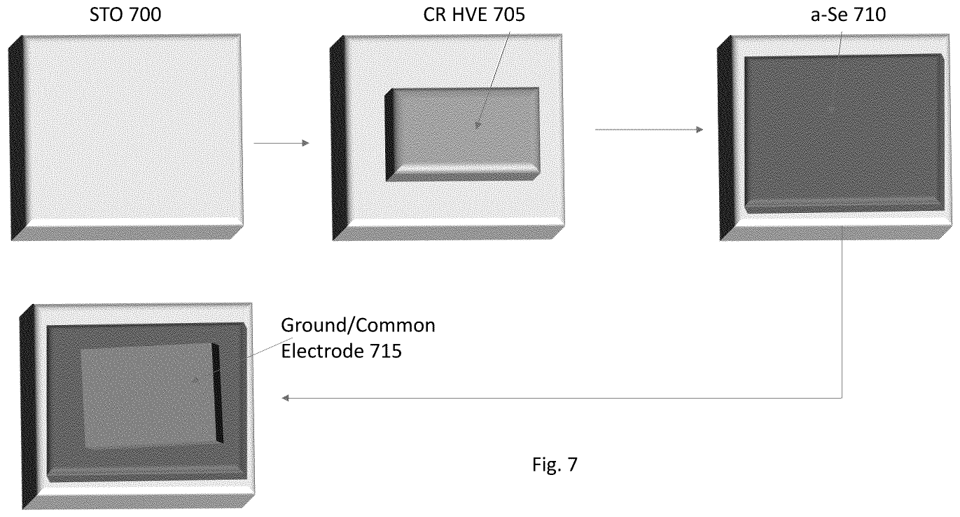

An avalanche detector in accordance with aspects of the disclosure was fabricated. This avalanche detector did not have an EBL 12. The avalanche detector was evaluated for avalanche gain and dark current density. FIG. 7 illustrates a step-by-step process of fabricating the test avalanche detector (“test detector”) in accordance with aspects of the disclosure.

The test detector 800 started as single crystal STO 700. The STO 700 had a κ of 300 and an optical bandgap of 3.3 eV. The STO 700 had a thickness of 500 μm. A Cr metal layer (HVE 705) was deposited on the STO 700 using DC sputtering. The thickness was 200 nm. On the other side of the STO, the a-Se layer 710 was deposited by thermally evaporating 99.99% pure selenium pellets under a vacuum (2×10⁻⁶ Torr at 50° C.). The a-Se layer was 8 μm thick. The ground electrode 715 was fabricated by DC sputtering onto the thermally deposited a-Se layer 710. The thickness was 200 nm. Cr was used as the ground/command electrode.

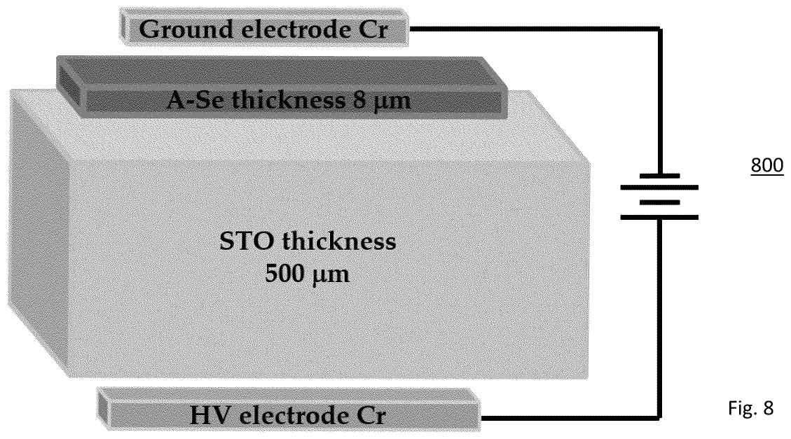

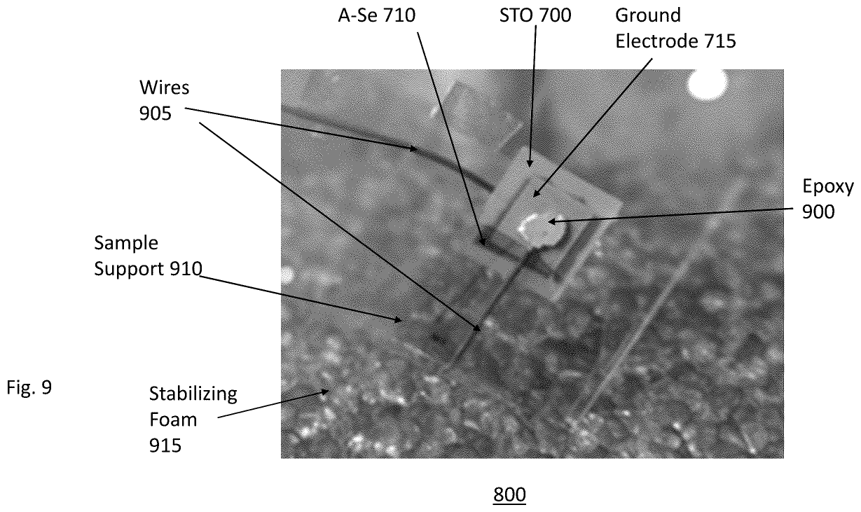

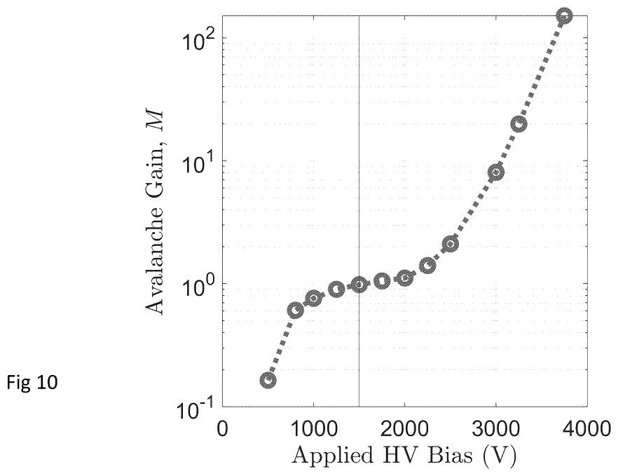

FIG. 8 illustrates a schematic of the test detector 800. FIG. 9 illustrates a test sample for the detector (DUT). The test sample 800 was fabricated on a sample support 910 for stability. Also, during testing, the test sample 800 was rested on a stabilizing foam 915. The wires 905 were attached to the respective electrodes using an epoxy 900. In the view in FIG. 9, the HVE electrode is hidden, however, the wire 905 connected to the electrode is shown. FIG. 9 shows the a-Se 710 sandwiched between the Ground/Common Electrode 715 and the STO 700. Tape was used to hold the test sample 800 together. The effective quantum efficiency (gain) and dark/leakage current was measurement over a wide range of bias conditions. The bias voltage was varied from 500 V to 3750V. FIG. 10 illustrates the measurement results of the avalanche gain as a function of the applied bias voltage. The applied bias voltage is on the x-axis and the avalanche gain, M is on the y-axis. The use of the STO (with the high κ of 300) enables a gain of about 150 at 3750 V for the 8 μm a-Se layer 710. Carriers in the a-Se layer 710 get hot at high electric fields and produce single-carrier impact ionization avalanche, resulting in enhanced effective quantum efficiency.

Different layers thickness may impact the gain.

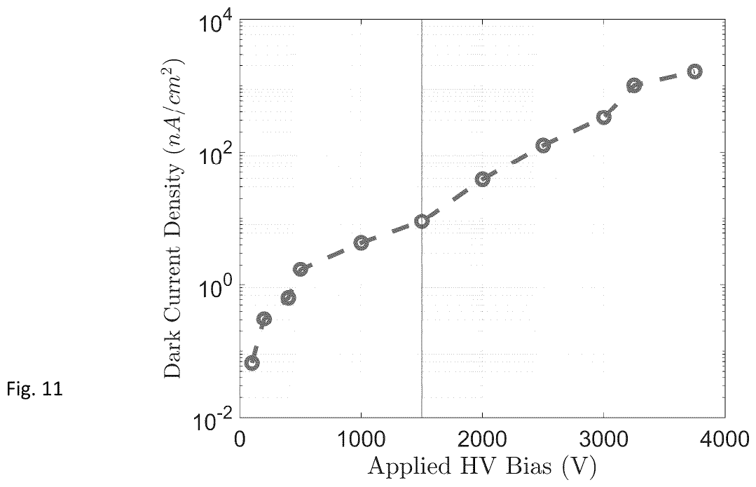

FIG. 11 illustrates the measurement results of the dark current density as a function of the applied bias voltage. The applied bias voltage is on the x-axis and the dark current density is on the y-axis. Beyond 3750 V, the device encountered a soft breakdown localized and randomly distributed over the device area.

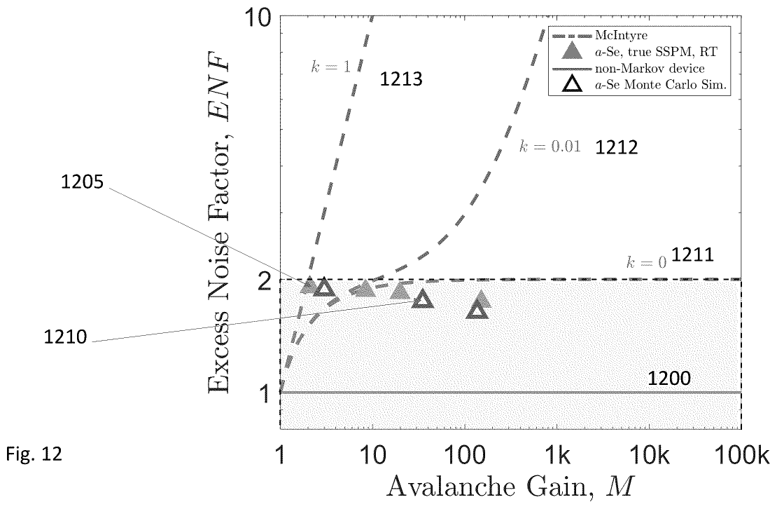

FIG. 12 illustrates both measurement results from the test detector 800 and simulate results for a device having the same properties and thicknesses. The graph illustrates excess noise factor (ENF) as a function of avalanche gain, M. The measurements were done at room temperature (RF). The measurements 1205 are shown with filled in triangles (4). The noise spectral density was measured using an SRS 865A lock-in-amplifier operated in current input mode. The spectral method was used to calculate the excess noise. The different avalanche gains were obtained by varying the bias voltage (and electric field). The hole-only, history dependent (non-Markovian), room temperature impact ionization process is represented by the filled in triangles. The measured ENF was between about 1.7 and about 1.9. The fluctuations in the avalanche gain (ENF) get progressively worse as the multiplication factor is increased in the avalanche photodiodes (APDs) by raising the electric field. The ideal non-Markov device ENF of 1 is denoted by the line 1200.

According to McIntyre theory, the slope of the gain versus ENF is a strong function of the ratio of two carriers (holes and electrons) ionization rate k where 0≤k≤1. The curves for three different k values are shown in FIG. 12 (curve 1211 k=0, curve 1212 k=0.01 and curve 1213 k=1). The measured excess noise in test detector 800 is because of the single carrier non-Markov branching of hot holes (due to many photon scattering events before a successfully non-ballistic impact ionization event).

Triangles 1210 represent a calculated ENF of 250,000 Monte Carlo hole trajectories (simulated). The measured ENF matches closely with the simulated results.

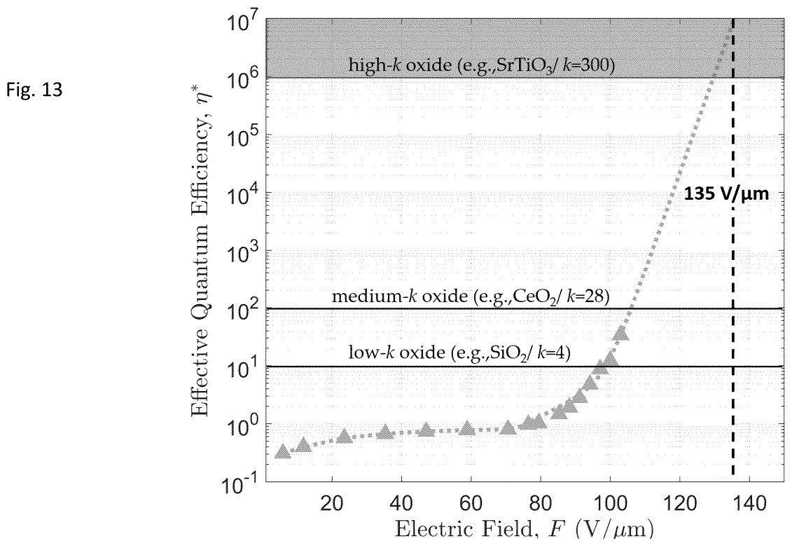

FIG. 13 illustrates a comparison between detectors having different HBL. Two detectors were fabricated having different κ for the HBL. The a-Se layer for the two detectors was 15 μm. Insulating HBL (SiO₂) was deposited on the a-Se layer with RF sputtering. SiO₂ has a κ value of 4. A non-insulating solution processed CeO₂ was deposited on the a-Se layer. The CeO₂ had a κ value of 28. Measured values are shown in triangles. Both detectors had avalanche gains at fields exceeding 80 V/m. The detector with the SiO₂ as the HBL had a maximum avalanche gain of 10. The maximum measured value from the detector having the CeO₂ as the HBL was about 40. However, theoretical, the maximum from that detector is around 100.

A fit, using a double exponential, was used to predict the avalanche gain from the detector with SrTiO₃ as the HBL for the 15 μm a-Se. The avalanche gain in a-Se is exponential as a function of higher fields. It is predicted for the 15 μm a-Se that the avalanche gain for the detector would be 10⁶ at about 150 V/μm. A vertical dashed line represents a field threshold of 135 V/μm. The dotted curve represents the prediction (fit curve).

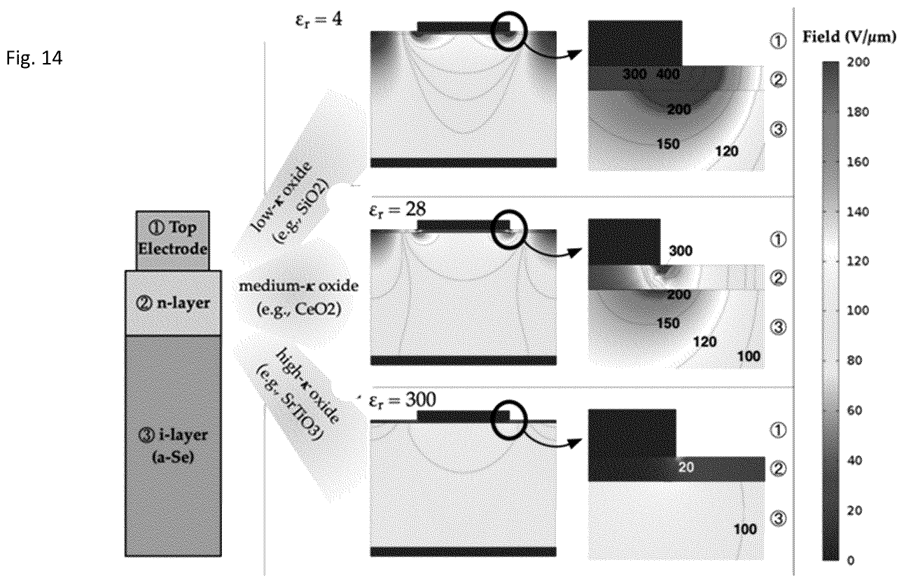

FIG. 14 illustrates simulated detector and simulation results for three different detectors have the different HBL (n-layer) (e.g., different κ value). The same different materials (used in FIG. 13), e.g., SiO₂, CeO₂ and SrTiO₃ were used for the technology computer-aided design (TCAD) simulations. n-i detectors were simulated with the top electrode, the n-layer and the i layer. For the i-layer in the simulations a-Se was used. In all three simulations, the electric field inside the bulk was 100. However, as can be seen from both detectors with the SiO₂ and CeO₂ as the HBL, there were significant hot-spots present. For example, when using the SiO₂ as the n-layer (HBL), the electric field hot-spot at the top electrode/HBL interface was 400 V/μm. There was some improvement using the CeO₂ as the HBL, however, there were still hop-spots over 200 V/μm and in fact, above 300 V/μm at the top electrode/HBL interface.

However, using the SrTiO₃ in a manner as described herein, the field hot-spots are completely erased as expected. The electric field is effectively contained within the a-Se (i-layer). Since the electric field is maintained within the a-Se, the electrodes may be cold to the touch (i.e., will have a low-filed interface and thus, low injection).

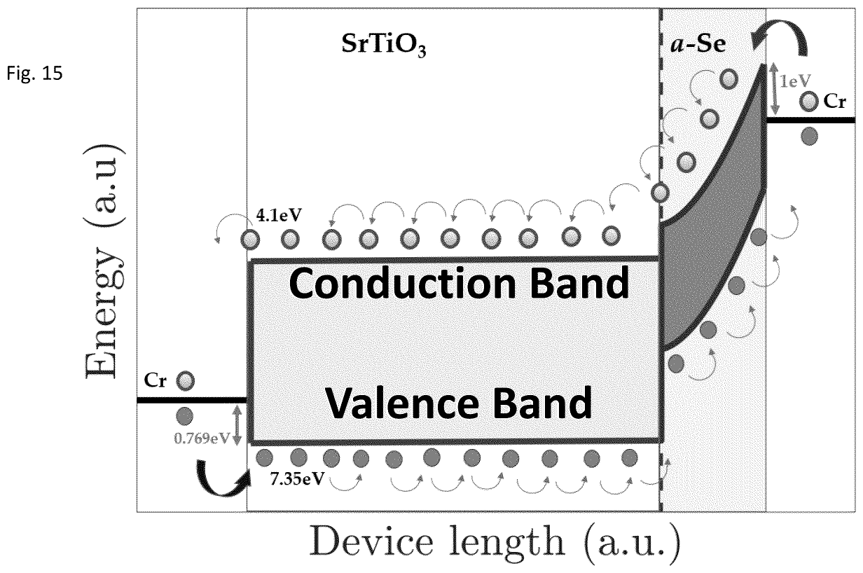

FIG. 15 illustrates a simulated energy band diagram for an n-i detector in accordance with aspects of the disclosure. A simulated bias voltage was applied to the n-i detector. The i-layer is a-Se. The n-layer is a hole blocking layer made of SrTi0₃. Light absorbed through a semi-opaque electrode (Cr) in the a-Se layer leads to the generation of electron-hole pairs in the i-layer (a-Se). The electron is excited from a valence to a conduction band, leaving behind a hole. The applied bias creates an energy gradient that separates an electron-hole pair. The holes travel towards a ground electrode and avalanche in the process. Specifically, the holes travel across the a-Se and are collected at the ground electrode (Cr) while the electrons travel across the single crystal STO and are collected at the HV electrode (Cr). FIG. 15 illustrates the hopping (holes are hopping toward the Cr ground (closer to axis) and electrons are hopping away from the axis. At high electric fields, hole transport in a-Se shifts from localized hopping to extended state band-like transport. The conduction band and the valance band are shown. The conduction band within the STO has an energy of 4.1 eV and the valance band within the STO has an energy of 7.35 eV. The slope of the bands depends on the applied bias.

The STO does not hinder the flow of the electrons. The hole injection barrier was simulated to be about 0.769V. The election injection barrier was simulated to be about 1 eV.

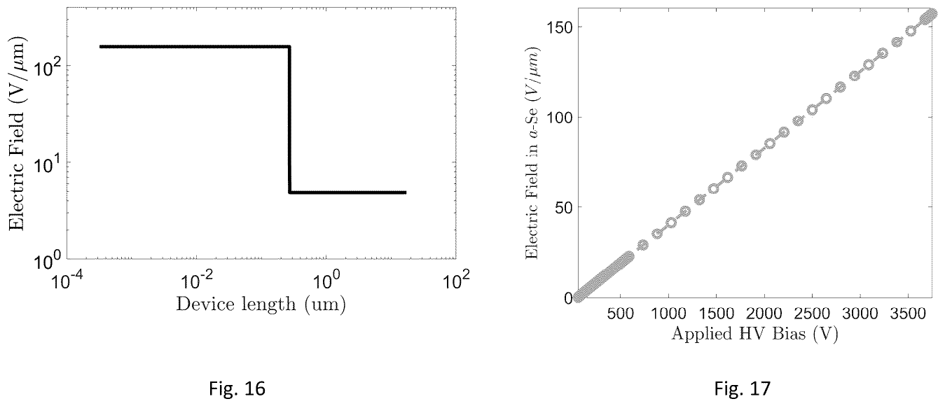

FIG. 16 illustrates the electric filed distribution over the thickness of the device. In FIGS. 15, 16 and 18, the device length is the thickness. The applied bias is 3750 V. As shown, most of the electric field is in the a-Se layer which enables the impact ionization avalanche. FIG. 16 is consistent with FIG. 14 where the electric field is limited to the a-Se layer and not in the STO.

FIG. 17 illustrates the electric field within the a-Se layer as a function of the applied bias voltage. The electric field is approximately linear with respect to the applied bias voltage. The high-κ STO layer enabled the 8 μm thick a-Se i-layer to withstand electric fields more than 150 V/μm. With a a-Se layer of about 15 μm, avalanche gains in the range of 10⁶-10⁸ can be achieved at ˜150 V/μm. as shown in FIG. 13.

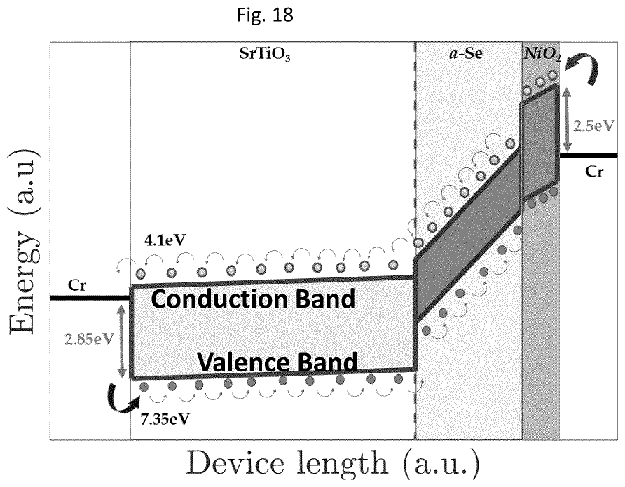

FIG. 18 illustrates a simulated energy band diagram for an n-i-p detector (simulated) with an applied bias voltage in accordance with aspects of the disclosure. The i-layer is a-Se. The n-layer is a hole blocking layer made of SrTi0₃. The p-layer, electron blocking layer was NiO₂. NiO₂ has a wide band-gap. With a wide-range of tunable carrier concentrations, NiO₂ has been used in a variety of applications, such as visible-transparent UV photodetectors, visible-transparent solar cells, and UV to visible spectrum light-emitting diodes. NiO₂ is also transparent.

The energy band diagram predicts an increase in electron injection barrier to 2.5 eV (enhanced). The increase helps decrease the electron component of the dark injection current even further. Moreover, there is enhancement of charge sensing by avalanche multiplication as the device is protected from localized Joule heating effects.

This prediction also has an increased hole injection barrier to 2.85 eV. The difference in the hole injection barrier in FIG. 18 versus FIG. 15 is that in FIG. 18, the model assumes an ideal and optimized interface between the Cr electrode and the STO. This assumption was not used in FIG. 15 (unoptimized interface was used resulting in a smaller simulated value). The conduction band and the valence band have different slopes in FIGS. 15 and 18. As noted above, this is because a different bias was applied in the different simulations.

In the discussion and claims herein, the term “about” indicates that the value listed may be somewhat altered, as long as the alteration does not result in nonconformance of the process or device. For example, for some elements the term “about” can refer to a variation of ±0.1% for other elements, the term “about” can refer to a variation of ±1% or ±10%, or any point therein. For example, the term about when used for a measurement in mm, may include +/0.1, 0.2, 0.3, etc., where the difference between the stated number may be larger when the state number is larger. For example, about 1.5 may include 1.2-1.8, where about 20, may include 19.0-21.0.

Reference herein to any numerical range expressly includes each numerical value (including fractional numbers and whole numbers) encompassed by that range. To illustrate, reference herein to a range of “at least 50” or “at least about 50” includes whole numbers of 50, 51, 52, 53, 54, 55, 56, 57, 58, 59, 60, etc., and fractional numbers 50.1, 50.2 50.3, 50.4, 50.5, 50.6, 50.7, 50.8, 50.9, etc. In a further illustration, reference herein to a range of “less than 50” or “less than about 50” includes whole numbers 49, 48, 47, 46, 45, 44, 43, 42, 41, 40, etc., and fractional numbers 49.9, 49.8, 49.7, 49.6, 49.5, 49.4, 49.3, 49.2, 49.1, 49.0, etc.

As used herein terms such as “a”, “an” and “the” are not intended to refer to only a singular entity, but include the general class of which a specific example may be used for illustration. As used herein, terms defined in the singular are intended to include those terms defined in the plural and vice versa.

References in the specification to “one aspect”, “certain aspects”, “some aspects” or “an aspect”, indicate that the aspect(s) described may include a particular feature or characteristic, but every aspect may not necessarily include the particular feature, structure, or characteristic. Moreover, such phrases are not necessarily referring to the same aspect. Further, when a particular feature, structure, or characteristic is described in connection with an aspect, it is submitted that it is within the knowledge of one skilled in the art to affect such feature, structure, or characteristic in connection with other aspects whether or not explicitly described.

The described aspects and examples of the present disclosure are intended to be illustrative rather than restrictive, and are not intended to represent every aspect or example of the present disclosure. While the fundamental novel features of the disclosure as applied to various specific aspects thereof have been shown, described and pointed out, it will also be understood that various omissions, substitutions and changes in the form and details of the devices illustrated and in their operation, may be made by those skilled in the art without departing from the spirit of the disclosure. For example, it is expressly intended that all combinations of those elements and/or method steps which perform substantially the same function in substantially the same way to achieve the same results are within the scope of the disclosure. Moreover, it should be recognized that structures and/or elements and/or method steps shown and/or described in connection with any disclosed form or aspects of the disclosure may be incorporated in any other disclosed or described or suggested form or aspects as a general matter of design choice. Further, various modifications and variations can be made without departing from the spirit or scope of the disclosure as set forth in the following claims both literally and in equivalents recognized in law.

1. A photomultiplier comprising:
a first electrode:
a hole blocking layer comprising a n-type material having a dielectric constant of at least 50;
an a-Se photoconductive layer;
an electron blocking layer comprising a p-type material; and
a second electrode, wherein the a-Se photoconductive layer is between the hole blocking layer and the electron blocking layer, wherein the hole blocking layer is between the first electrode and the a-Se photoconductive layer and the electron blocking layer is between the second electrode and the a-Se photoconductive layer.

2. The photomultiplier of claim 1, wherein the n-type material is SrTi0₃.

3. The photomultiplier of claim 2, wherein an avalanche gain about 150 at an applied bias of about 3750 V.

4. The photomultiplier of claim 2, wherein the SrTi0₃ is a single crystal.

5. The photomultiplier of claim 4, wherein the dielectric constant of the single crystal is 300.

6. The photomultiplier of claim 1, wherein the hole blocking layer has a thickness of about 50 nm to about 1 μm.

7. The photomultiplier of claim 1, wherein the first electrode is transparent.

8. The photomultiplier of claim 1, wherein the first electrode is indium tin oxide (ITO).

9. The photomultiplier of claim 1, wherein the dielectric constant of the n-type material is between about 50 and about 3000.

10. The photomultiplier of claim 1, wherein the p-type material is Ni0₂.

11. The photomultiplier of claim 1, wherein the p-type material has a dielectric constant of at least 50.

12. The photomultiplier of claim 1, further comprising a readout device.

13. The photomultiplier of claim 1, wherein the n-type material is selected from a group consisting of Barium Titanate, Strontium Titanate, Barium Strontium Titanate, and Titanium Oxide.

14. The photomultiplier of claim 1, wherein the a-Se photoconductive layer has a thickness between about 500 nm and about 35 μm.

15. A photomultiplier comprising:
a first electrode:
a hole blocking layer comprising SrTi0₃;
an a-Se photoconductive layer;
an electron blocking layer comprising a p-type material; and
a second electrode, wherein the a-Se photoconductive layer is between the hole blocking layer and the electron blocking layer, wherein the hole blocking layer is between the first electrode and the a-Se photoconductive layer and the electron blocking layer is between the second electrode and the a-Se photoconductive layer.

16. The photomultiplier of claim 15, wherein an avalanche gain is about 150 at applied bias of about 3750 V.

17. The photomultiplier of claim 15, wherein the SrTi0₃ is a single crystal.

18. The photomultiplier of claim 17, wherein the dielectric constant of the single crystal is 300.

19. The photomultiplier of claim 15, wherein the p-type material is Ni0₂.

20. A method of manufacturing a photomultiplier comprising:
fabricating a first part of the photomultiplier;
fabricating a second part of the photomultiplier; and
combining the first part and the second part, wherein fabricating the first part comprises:
depositing an electron blocking layer comprising a p-type material on a readout device; and
depositing a first portion of a-Se photoconductive layer having a first thickness of the electron blocking layer,
wherein fabricating the second part comprises:
depositing a hole blocking layer comprising a n-type material having a dielectric constant of at least 50 on a substrate, where the substrate comprising an electrode; and
depositing a second portion of a-Se photoconductive layer having a second thickness on the hole blocking layer,
wherein the combining comprises:
heating the first part and the second part to at least a glass transition temperature of the a-Se photoconductive layer; and
applying pressure to fuse the first portion of the a-Se photoconductive layer and the second portion of the a-Se photoconductive layer thereby combining the first part and the second part,
wherein the readout device has common electrode.

21. The method of claim 20, wherein the first thickness and the second thickness are the same.

22. The method of claim 20, wherein the p-type material is Ni0₂.

23. The method of claim 20, wherein the n-type material is selected from a group consisting of Barium Titanate, Strontium Titanate, Barium Strontium Titanate, and Titanium Oxide.

24. The method of claim 23, wherein the n-type material is Strontium Titanate.

25. A method of manufacturing a photomultiplier comprising:
depositing an electron blocking layer comprising a p-type material on a readout device where the readout device has a common electrode;
thermally depositing a-Se layer on the electron blocking layer;
depositing at a temperature less than a glass transition temperature of the a-Se layer, a hole blocking layer comprising a n-type material having a dielectric constant of at least 50; and
depositing another electrode on the hole blocking layer.

26. The method of claim 25, wherein the hole blocking layer is RF sputtered.

27. The method of claim 25, wherein the n-type material is selected from a group consisting of Barium Titanate, Strontium Titanate, Barium Strontium Titanate, and Titanium Oxide.

28. The method of claim 27, wherein the n-type material is Strontium Titanate.

29. The method of claim 25, wherein the p-type material is NiO₂.
